(19) United States
(12) Patent Application Publication
(10) Pub. No.: US 2008/0055252 A1
(43) Pub. Date: Mar. 6, 2008

(54) Operation panel apparatus and electric apparatus provided with the same

(75) Inventors: Kouji Miyake, Yamatokooriyama-shi (JP); Tsutomu Yoshimoto, Yamatotakada-shi (JP); Hideyuki Hiro, Tenri-shi (JP)

Correspondence Address: BIRCH STEWART KOLASCH & BIRCH, PO BOX 747, FALLS CHURCH, VA, 22040-0747, US

(73) Assignee: SHARP KABUSHIKI KAISHA

(21) Appl. No.: 11/896,432

(22) Filed: Aug. 31, 2007

(30) Foreign Application Priority Data
Sep. 4, 2006 (JP) 2006-239211
Sep. 4, 2006 (JP) 2006-239216

(51) Int. Cl. G06F 3/02; H03M 11/00

(52) U.S. Cl. 345/168; 341/22; 345/156; 345/173

(57) ABSTRACT

To provide an operation panel apparatus which can be used without exchanging the whole operation panel, even when input of a part of an input apparatus cannot be performed. In a test mode, a plurality of fixed keys 7 are in sequence checked on whether or not the input of the plurality of fixed keys 7 can be performed. A detecting portion 18 judges the fixed key as an input-enabled fixed key 7a by detecting that the input from the fixed key 7 is sensed, and judges the fixed key as an input-disabled fixed key 7b by detecting that the input from the fixed key 7 is not sensed. When the input-disabled fixed key 7b exists, a substitute control portion 19 displays a touch key 5a substituting for the function of the input-disabled fixed key 7b in a display screen.

### BACKGROUND OF THE INVENTION

1. Field of the Invention

The present invention relates to an operation panel apparatus provided with an operation panel for inputting an operation instruction.

2. Description of the Related Art

An electric apparatus, such as a copy machine, a printer, a facsimile, a scanner, and a composite machine constituted by combining these, is provided with an operation panel including operation input keys, such as a start button and a temporary stop button, corresponding to respective operations. The operation panel is provided with fixed keys, such as a ten key, a start key, and a cancel key, which are frequently used. These fixed keys perform electric connection and disconnection by mechanical contacts.

Meanwhile, when the mechanical contacts of the fixed key wear out due to use over a long period of time and severe environmental changes, the fixed key may become incapable of normally detecting input. For such a case, there is disclosed an exchanging method in Japanese Patent Laid-Open No. 01-167925, which is adapted to shorten repair time and to reduce repair cost by exchanging only a failed key.

Further, there is disclosed a method in Japanese Patent Laid-Open No. 07-066885, in which a lifetime set value of an operation panel is stored in advance, and a lifetime set value is calculated on the basis of the use frequency of the operation panel, and in which when the calculated life value approaches the stored life set value, the notification is provided to a user so that the operation panel is exchanged, thereby shortening the repair time of the operation panel.

Meanwhile, in Japanese Patent Laid-Open No. 01-167925, only a failed fixed key is exchanged. From the viewpoint of service, however, not only the failed fixed key but also the whole fixed keys are generally exchanged. Further, the mechanical key may be unexpectedly failed, for example, may be failed by a strong striking force, water drops or the like. In the method disclosed in Japanese Patent Laid-Open No. 07-066885, such failure is not taken into consideration.

Therefore, it is an object of the present invention to provide an operation panel apparatus which can be used without exchanging the whole operation panel, even when a part of input keys of the operation panel become incapable of performing input.

### SUMMARY OF THE INVENTION

In order to achieve the above described object, according to the present invention, there is provided an operation panel apparatus characterized by including an operation panel for input operation, a detecting portion adapted to detect an input-disabled key incapable of performing input in the operation panel, and a substitute control portion adapted, when the input-disabled key is detected, to control the operation panel to enable the other input-enabled key to cope with the input instead of the input-disabled key.

The operation panel includes a display apparatus having a contact type or non-contact type input mechanism, and an input apparatus having a mechanical input mechanism. The operation panel receives an operation input from a user through the display apparatus or the input apparatus. Meanwhile, an input-disabled key is generated due to service life or failure. The input-disabled key means an input key by means of which an operation input cannot be performed from the operation panel.

Thus, the operation input is adapted to be able to be performed in such a manner that the detecting portion detects the input-disabled key, and the substitute control portion controls the operation panel to enable the other input-enabled key to cope with the operation input instead of the input-disabled key detected by the detecting portion.

Specifically, the operation panel apparatus is characterized in that the operation panel includes an input apparatus having a plurality of fixed keys, in that the detecting portion detects an input-disabled fixed key, which is incapable of performing input, among the plurality of fixed keys, and in that when the input-disabled fixed key exists, the other fixed key is adapted to cope with the input instead of the input-disabled fixed key.

In an input apparatus, when an input-disabled fixed key is detected, a fixed key corresponding to the input-disabled fixed key is determined in the other input apparatus. When the substitute fixed key is operated by the user, the same input operation as that when the input-disabled fixed key is operated can be performed. That is, the function assigned to the input-disabled fixed key is assigned to the substitute fixed key. As a result, even when an unusable fixed key exists, a fixed key substituted for the unusable fixed key can be used without causing inconvenience to the user.

The substitute fixed key is newly provided in the other input apparatus. For example, in an input apparatus such as a touch panel, it is possible to cope with the input-disabled fixed key by forming a new fixed key other than the existing fixed keys.

The operation panel apparatus is characterized by including a plurality of input apparatuses, and in that the detecting portion has a test mode for operating a plurality of fixed keys in one of the input apparatuses, and judges whether the each fixed key is an input-enabled key whose input is effective, or an input-disabled key whose input is ineffective, by performing the test mode. When the user becomes aware of abnormality at the time of operating a fixed key, it is possible for the user to specify the input-disabled fixed key by performing the test mode.

In this case, the test mode is performed by an input operation from the other input apparatus. That is, a fixed key for test for performing the test mode is provided in the input apparatus. When this fixed key is operated, the test mode is performed. When an input-disabled fixed key exists in one input apparatus, it may not be possible to perform input from the fixed key for test. However, the test mode can be surely performed by operating the fixed key for test in the other input apparatus.

Here, in a specific operation panel apparatus which includes an input apparatus and a display apparatus, the input apparatus has fixed keys to which predetermined functions are respectively assigned, and the display apparatus has touch keys formed on a display screen. Therefore, when the operation panel apparatus is used for a long period of time, mechanical components may deteriorate, and abnormality may occur only in a part of the fixed keys due to the ingress of foreign matter. For this reason, there are provided the detecting portion adapted to detect an input-disabled fixed key, which is incapable of performing input, among the plurality of fixed keys, and the substitute control portion adapted, when the input-disabled fixed key exists, to enable the touch key of the other input apparatus to cope with the input instead of the input-disabled fixed key.

The detecting portion specifies the input-disabled fixed key by performing the test mode. The substitute control portion provides the touch key to be used as a substitute of the fixed key in the display screen.

Also, the substitute control portion assigns the function assigned to the input-disabled fixed key to the substitute touch key. When the user operates the touch key substituting for the fixed key, the touch key inhibits the same function as that of the input-disabled fixed key.

The substitute control portion changes the display of the display screen to secure a space for forming the substitute touch key. Since the touch key is newly provided, there is no problem when a free space enough to form the touch key is available in the display screen. However, when a sufficient free space is not available, the substitute control portion shifts the display of the display screen to create a space for forming the new touch key. Note that the forming position of the touch key may be freely set so as to be easily used by the user.

In this way, in the operation panel having the display apparatus, a touch key can be easily provided, which makes it possible for the user to perform input even when the input of a fixed key of an input apparatus is disabled.

In another example, the operation panel is characterized by including a display apparatus having a display screen by means of which input can be performed, in that a detecting portion is adapted to detect an input-disabled region in which the input cannot be performed in the display apparatus, and in that the substitute control portion is adapted, when the input-disabled region exists, to control the display apparatus to perform the display in a manner of avoiding the input-disabled region.

The display apparatus includes a contact type or non-contact type input mechanism, and receives an operation input from the user via the display screen. Meanwhile, the input-disabled region may be generated in the display screen due to the service life or a failure. The input-disabled region means a region in which an operation input cannot be performed from the display screen, or a region in which a part of the display screen is not displayed and the operation input cannot be performed.

Therefore, it is adapted such that the input-disabled region is detected by the detecting portion, and the arrangement of the display screen is changed by the substitute control portion, so as to avoid the detected input-disabled region.

Specifically, in the operation panel apparatus, there is provided a specifying portion adapted to specify an input-disabled region and an input-enabled region on the basis of the detection result. The substitute control portion displays a position arranged to avoid the specified input-disabled region, that is, an input frame indicating an input position in the input-enabled region in which input can be performed, and displays an input guide indicating the contents of the input in the input-disabled region, or inhibits the display.

According to the above described constitution, even when the input from the display apparatus is partially disabled, the input frame is arranged in the position in which the operation input can be performed, and hence the operation panel can be continuously used without being exchanged as a whole.

Further, the display screen is divided into a plurality of input regions. The detecting portion in sequence checks whether or not the each divided area is in the input-enabled state. The specifying portion sets the input region from which an input is detected as an input-enabled region, and sets the input region from which an input cannot be detected as an input-disabled region.

The detecting portion is operated by a command from the input apparatus provided separately from the display screen. Even when a part of the display screen becomes an input-disabled region, the detecting portion can be operated by the operation input from the input apparatus.

The substitute control portion determines whether or not the display apparatus can be used on the basis of a ratio of the input-disabled region to the input-enabled region. The substitute control portion inhibits the use of the display apparatus when the input-disabled regions are large enough to hinder the input. When the input-disabled region is small so that the corresponding operation can be performed by changing the display, the substitute control portion enables the display apparatus to be used.

For example, when the display screen consists of an input region divided into a plurality of sections and the input-disabled region continuously exists across the plurality of sections, the substitute control portion inhibits the use of the display apparatus.

When the input frame indicating the input position and the input guidance indicating the input contents are displayed in the operation screen, and a plurality of input frames are displayed in the display screen, and when an input-disabled region exists, the display control means performs a display so as to restrict the input by reducing the input frames. In this case, the usable functions are reduced, but the fundamental functions can be used. That is, the minimum functions in the image processing apparatus provided with the operation panel can be achieved.

When the input-disabled region is detected, the substitute control portion creates a trouble history about the input-disabled key. Here, the trouble history means a history about an input key by means of which an operation input cannot be performed from the operation panel. The trouble history is stored in a memory. Even after the apparatus is restarted, it is possible to make the other input-enabled key cope with the input instead of the input-disabled key.

### BRIEF DESCRIPTION OF THE DRAWINGS

FIG. 1 is a figure showing a schematic constitution of an image processing apparatus of a first embodiment;

FIG. 2 is a figure showing an operation panel;

FIG. 3 is a figure showing a screen for selecting a special function normally used in the first embodiment;

FIG. 4(A) is a figure showing a display screen of a test mode, especially with respect to a screen showing an operating procedure;

FIG. 4(B) is a figure showing a display screen of a test mode, especially with respect to a screen in which marks are displayed for the input-enabled fixed key and the input-disabled fixed key;

FIG. 5(A) is a figure showing a display screen of a test mode, especially with respect to a screen showing an operating procedure;

FIG. 5(B) is a figure showing a display screen of a test mode, especially with respect to a screen in which marks are displayed for the input-enabled fixed key and the input-disabled fixed key;

FIG. 6 is a figure showing a display screen of a test mode;

FIG. 7 is a figure showing a specified input-disabled fixed key;

FIG. 8(A) is a figure showing an input frame normally used and an arrangement screen of an input guide, especially with respect to a screen for selecting a copy density;

FIG. 8(B) is a figure showing an input frame normally used and an arrangement screen of an input guide, especially with respect to a screen for selecting a copy magnification;

FIG. 8(C) is a figure showing an input frame normally used and an arrangement screen of an input guide, especially with respect to a screen for selecting a special function;

FIG. 8(D) is a figure showing an input frame normally used and an arrangement screen of an input guide, especially with respect to a screen for selecting the double side copying;

FIG. 9(A) is a figure showing a screen in which the arrangement of the input frame and the input guide is changed, especially with respect to an operation screen in a standby state;

FIG. 9(B) is a figure showing a screen in which the arrangement of the input frame and the input guide is changed, especially with respect to a screen for selecting a copy density;

FIG. 9(C) is a figure showing a screen in which the arrangement of the input frame and the input guide is changed, especially with respect to a screen for selecting a copy magnification;

FIG. 9(D) is a figure showing a screen in which the arrangement of the input frame and the input guide is changed, especially with respect to a screen for selecting a special function;

FIG. 9(E) is a figure showing a screen in which the arrangement of the input frame and the input guide is changed, especially with respect to a screen for selecting the double side copying;

FIG. 10 shows a flow chart from when an input-disabled fixed key is detected to when a substitute touch key is arranged;

FIG. 11 is a figure showing a schematic constitution of an image processing apparatus of a second embodiment;

FIG. 12 is a display screen of a touch panel test mode, and is a figure showing a screen in which an input region is divided into sections;

FIG. 13 is a display screen of a touch panel test mode, and is a figure showing a screen in which marks are displayed in the input-enabled region and the input-disabled region;

FIG. 14 is a figure showing the end of the touch panel test mode;

FIG. 15 is a figure showing the input-enabled region and the input-disabled region which are specified;

FIG. 16 is a figure showing an input frame normally used and an arrangement screen of an input guide;

FIG. 16(A) is a screen for selecting a copy density;

FIG. 16(B) is a screen for selecting a copy magnification;

FIG. 16(C) is a screen for selecting a special function;

FIG. 16(E) is a screen for selecting the double-side copying;

FIG. 17(A) is a figure showing a screen in which the arrangement of the input frame and the input guide is changed, especially with respect to a screen for selecting a copy density;

FIG. 17(B) is a figure showing a screen in which the arrangement of the input frame and the input guide is changed, especially with respect to a screen for selecting a copy magnification;

FIG. 17(C) is a figure showing a screen in which the arrangement of the input frame and the input guide is changed, especially with respect to a screen for selecting a special function; and

FIG. 17(D) is a figure showing a screen in which the arrangement of the input frame and the input guide is changed, especially with respect to a screen for selecting the double-side copying.

### DETAILED DESCRIPTION OF THE PREFERRED EMBODIMENTS

### First Embodiment

In the following, an image processing apparatus A provided with an operation panel 1 according to a first embodiment of the present invention will be described with reference to the accompanying drawings.

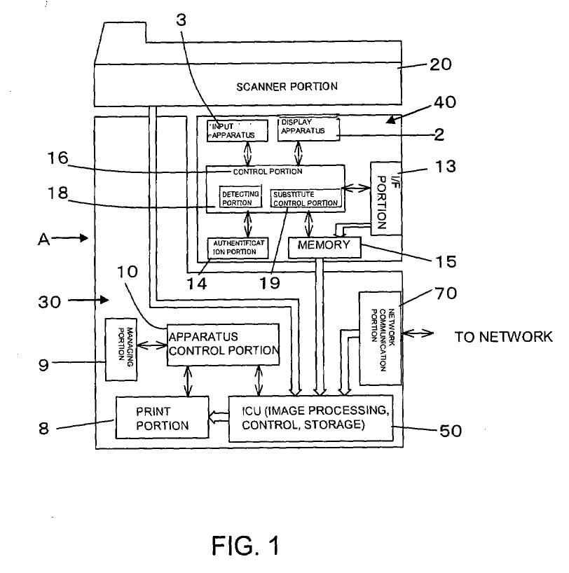

As shown in FIG. 1, the image processing apparatus A according to the present invention is a composite machine which performs a copy mode, a print mode, a scanner mode, and a facsimile mode, and which includes a scanner portion 20 adapted to read a document and to input an image data of the document, an image data processing portion 30 adapted to perform processing of the image data, and an information processing portion 40 adapted to perform processing of inputted information such as authentication information.

The image data processing portion 30 has an image processing portion 50 adapted to perform edit, storage and output processing of the inputted image data, a network communication portion 70 adapted to perform data communication via a network, a print portion 8 adapted to print the image data and output the printed image data, a managing portion 9 adapted to store control information, setting information and the like of the whole apparatus, and an apparatus control portion 10 adapted to perform control of the whole apparatus.

The image processing portion 50 includes a hard disk apparatus and a memory for storing the image data.

The information processing portion 40 has an input apparatus 3 for input operation, a display apparatus 2 adapted to display an operation screen, an interface portion 13 adapted to perform communication with a portable terminal apparatus such as an USB apparatus and an IC card, an authentication portion 14 adapted to perform authentication for inputted authentication information, a memory 15 adapted to store information such as the authentication information, and a control portion 16 adapted to perform processing of the operation information and the authentication information which are inputted. The communication by the interface portion 13 may be performed by wire or radio. The control portion 16 controls the display apparatus 2 to display an operation screen corresponding to the processing.

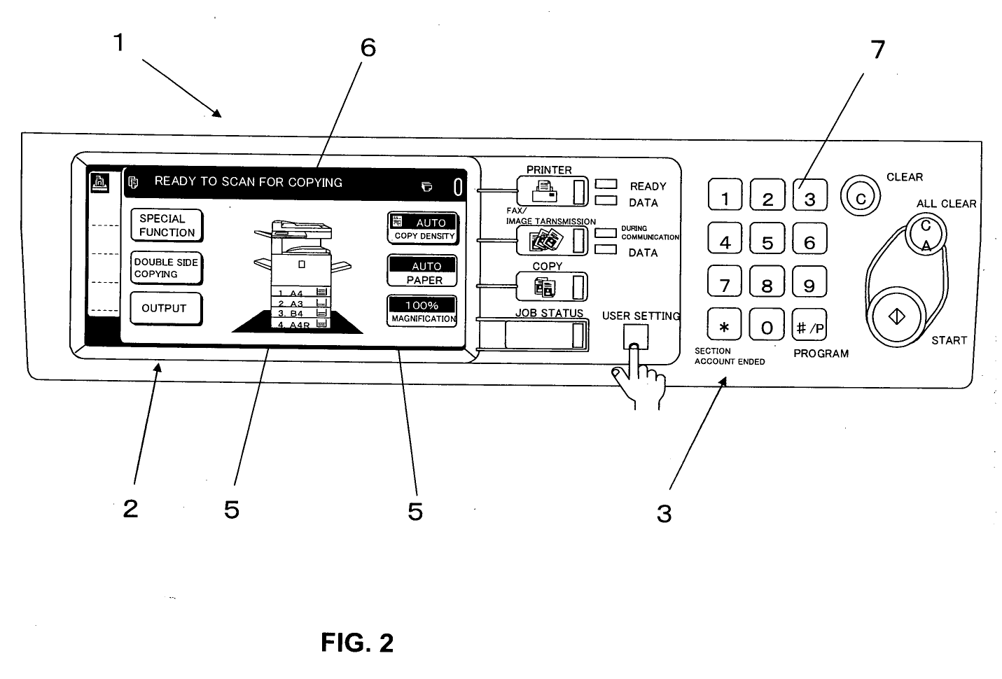

The input apparatus 3 and the display apparatus 2 are provided in the operation panel 1, as shown in FIG. 2. The display apparatus 2 has an electrostatic touch panel and a liquid crystal display. The input apparatus 3 has fixed keys 7 which perform input by being pressed down.

Also, the plurality of image processing apparatuses A are connected to the network, such as LAN and WAN. A plurality of external apparatuses are connected to the network. As the external apparatuses, a personal computer and a server are included. Note that the server is a management server which manages the whole system, an authentication server which authenticates a user, or the like. Further, the network has a router connected to the Internet via a communication line, such as a telephone line and an optical fiber. Further, the image processing apparatus A has a modem apparatus (not shown), and is capable of performing data communication with the facsimile apparatus through the telephone line.

The image processing apparatus A is adapted to be capable of performing communication with the external apparatus through the network on the basis of a predetermined communication protocol. Further, the image processing apparatuses A are adapted to be capable of performing communication with each other. Note that the communication within the network may be performed by wire or radio.

The image data are transmitted from the external apparatus to the image processing apparatus A through the network. The network communication portion 70 of the image processing apparatus A receives and inputs the image data. In the case of facsimile communication, the modem apparatus inputs the image data. Further, the image data is also inputted from the scanner portion 20.

Upon receipt of the image data, the apparatus control portion 10 performs one of the plurality kinds of processing of the print mode, the copy mode, the scanner mode, and the facsimile mode on the basis of a processing condition included in the input information from the input apparatus 3, and the header information of the inputted image data. In the print mode and the copy mode, after performing the image processing of the image data in the image processing portion 50, the apparatus control portion 10 makes the print portion 8 print an image on a recording sheet. In the scanner mode, the apparatus control portion 10 stores the image data in the hard disk apparatus, and transmits the image data to the external apparatus through the network communication portion 70 in response to a call from the external apparatus. In the facsimile mode, the apparatus control portion 10 transmits the image data to the facsimile apparatus through the modem apparatus.

Next, the display apparatus 2 has an electrostatic touch panel and a liquid crystal display as shown in FIG. 2. The touch panel is an input apparatus adapted to receive an operation input, when the panel surface is touched with a finger, a dedicated pen, or the like. The touch panel is constituted by an input region 4 divided into a plurality of sections. Further, the touch panel is constituted by a dedicated transparent screen, and attached so as to cover the upper surface of the liquid crystal display.

Here, the input region 4 is arranged in a matrix form, and an input is sensed by an operation such as touching the inside of the input region. The positional information relating to the input region 4 is outputted to the control portion 16.

The liquid crystal display is driven and controlled by the control portion 16 so that a touch key 5 indicating the input position is displayed on the screen in correspondence with the input region 4. Note that the touch key 5 means a display of an input key for selecting a function of specifying a paper sheet, enlarging/reducing a copy, adjusting print density, and the like, or a display of operating states such as an operation mode and an error message, or a display of information such as the explanation of the function. Further, a display dedicated region 6 having no input region 4 is provided in the liquid crystal display. The display dedicated region 6 displays operating states of the image processing apparatus A, information for notifying whether or not the display apparatus 2 can be used, or the like.

The input apparatus 3 has fixed keys 7 by means of which various inputs are performed, as shown in FIG. 2. The fixed key 7 has mechanical contacts, which are brought into contact and electrically connected with each other when the top of the fixed key 7 is pressed down. A detection signal generated at this time is inputted to the control portion 16. The control portion 16 discriminates the operated fixed key 7 on the basis of the detection signal, and outputs an operation signal corresponding to the function assigned to the fixed key 7 to the apparatus control portion 10.

The apparatus control portion 10 controls the operation of each portion on the basis of the operation command inputted from the fixed key 7 or the touch panel, and issues an instruction to the control portion 16 so as to make the liquid crystal display perform a display of an operation screen in correspondence with the operating state. The control portion 16 arranges and displays the touch key 5 in the liquid crystal display in correspondence with the input region 4 on the basis of the instruction from the apparatus control portion 10.

When the fixed key 7 fails due to use over a long period of time or severe environmental changes, the fixed key 7 is set as an input-disabled fixed key 7b by means of which input cannot be performed. The other fixed key 7 by means of which input can be performed is set as an input-enabled fixed key 7a by means of which input can be performed. Means for forming a touch key 5a substituting for the function of the input-disabled fixed key 7b will be explained. The control portion 16 includes a detecting portion 18 adapted to detect, among the respective fixed keys 7, the input-enabled fixed key 7a by means of which input can be performed and the input-disabled fixed key 7b by means of which input cannot be performed, and a substitute control portion 19 adapted to control the display apparatus 2 so that the touch key 5a substituting for the function of the detected input-disabled fixed key 7b is displayed in a free space of the display screen.

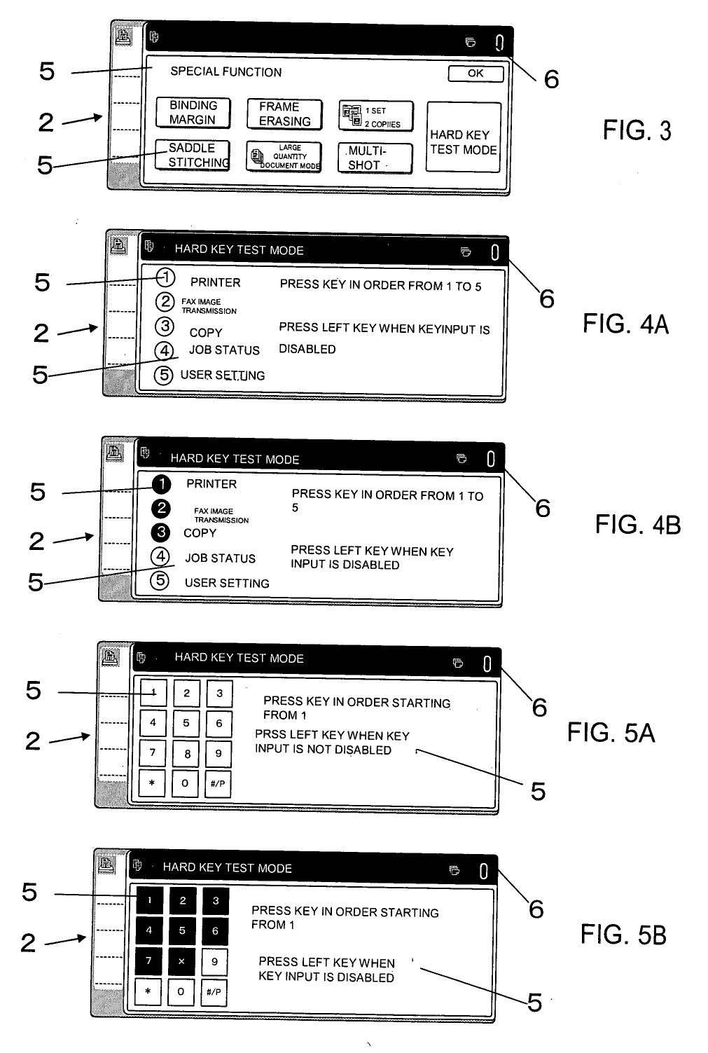

The detecting portion 18 detects the input-disabled fixed key 7b. Specifically, the control portion 16 performs a test mode for detecting whether or not the input from each fixed key 7 can be performed. The detecting portion 18 starts the operation of the test mode on the basis of the input from the touch key 5 on which “test mode” is written as shown in FIG. 3. As shown in FIG. 4 to FIG. 6, the fixed keys 7 and the functions assigned to the fixed keys 7 are displayed in the display screen. The input guide 6 is displayed so as to enable the user in sequence to press the respective fixed keys 7.

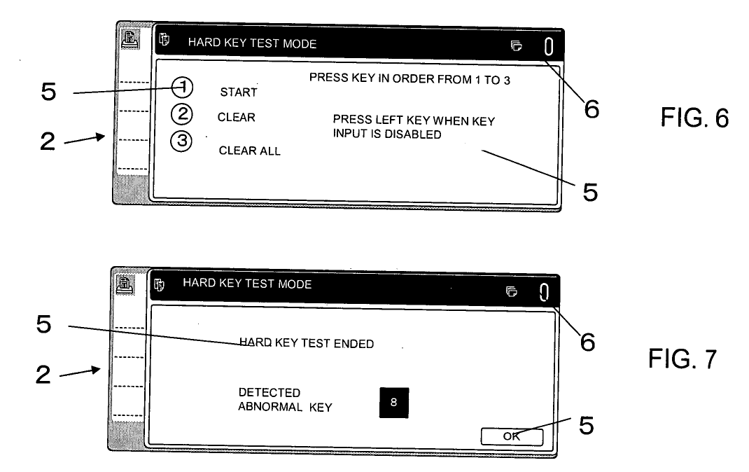

When sensing an input from the fixed key 7, the detecting portion 18 displays the inputted fixed key 7 by changing the color of the section of the fixed key 7. Further, when the input from the fixed key 7 is not detected, a different display is performed in the section of the fixed key. For example, in the case of the fixed key 7 for selecting a function, as shown in FIG. 4(A) and FIG. 6, each function and the number indicating the order of pressing the fixed keys corresponding to the functions are displayed. The display is performed so as to enable the user to in sequence press the respective fixed keys displayed in the display screen. When sensing an input from the fixed key 7, the detecting portion 18 displays the number of the detected fixed key 7, by changing the color of the fixed key, as shown in FIG. 4(B). Further, when sensing no input from the fixed key 7, the detecting portion 18 does not change the color of the number of the fixed key.

In the case where a fixed key 7 incapable of sensing the input exists, when the touch key 5 (the number attached to the function display in the case of the fixed key 7 for selecting a function) displayed in the display screen is pressed, the detecting portion 18 recognizes the fixed key 7 as a fixed key 7 incapable of detecting the input. Further, it may also be adapted such that when there is no input for a fixed time period after the display for requiring the input of a fixed key 7 is shown, the fixed key 7 is detected as the fixed key 7 incapable of sensing the input.

Further, in the case where the fixed key 7 is a ten key for inputting a numerical value, the ten key is displayed as shown in FIG. 5(A). The display is performed so as to make the user in sequence press the respective fixed keys 7 as the ten key displayed in the display screen. When sensing the input from a fixed key 7, the detecting portion 18 displays the detected fixed key 7 by changing the color thereof, as shown in FIG. 5(B). Further, when sensing no input from a fixed key 7, the detecting portion 18 makes a different display, for example, displays a mark “x” in the section of the fixed key 7.

Further, the detecting portion 18 specifies the input-enabled fixed key 7a and the input-disabled fixed key 7b on the basis of the result of the test mode. Specifically, when the test mode is ended as shown in FIG. 7, the detecting portion 18 stores “8” which is the input-disabled fixed key 7b, and the input-enabled fixed keys 7a other than the input-disabled fixed key 7b in the memory 15.

The substitute control portion 19 creates a trouble history including the specified input-disabled fixed key 7b, and stores the trouble history in the memory 15. Here, the trouble history means information on the occurrence date and time, the occurrence place, the occurrence state and the like, relating to the specified input-disabled fixed key 7b, a failure and the like in the process of conveyance, such as the paper jam of a recording paper, a document or the like, and the double feed of a recording paper, a document or the like.

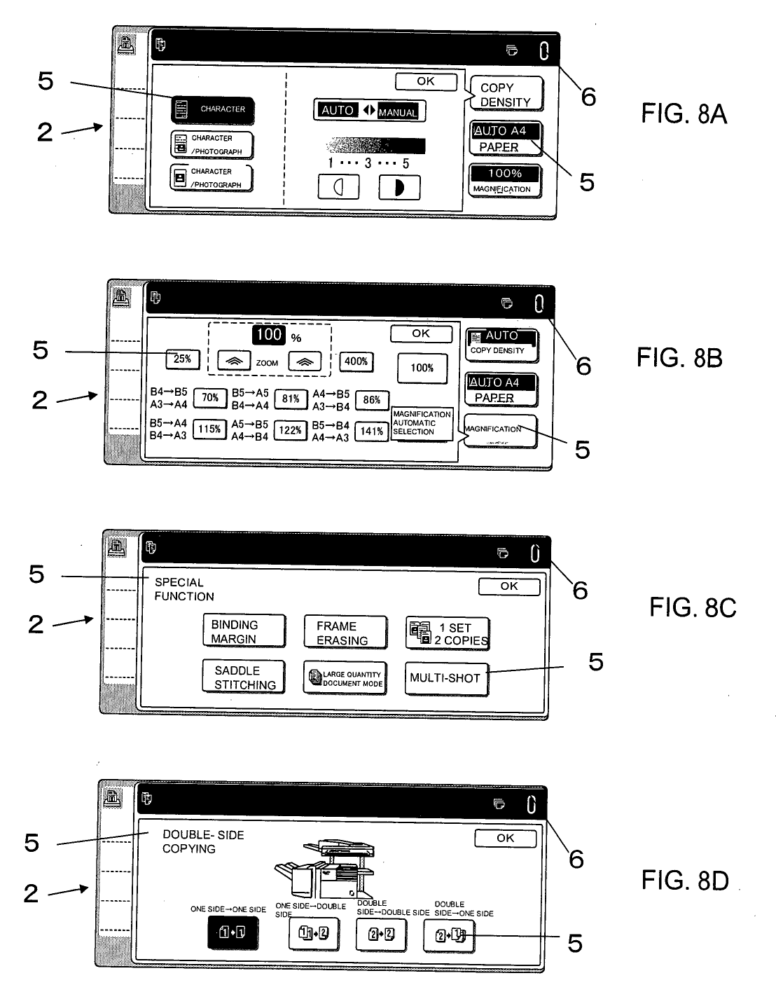

Further, the substitute control portion 19 determines the display position and the display contents of the touch key 5 to be displayed in the display screen. Specifically, the substitute control portion 19 arranges and displays the touch key 5 in correspondence with the input region 4, as shown in FIG. 8.

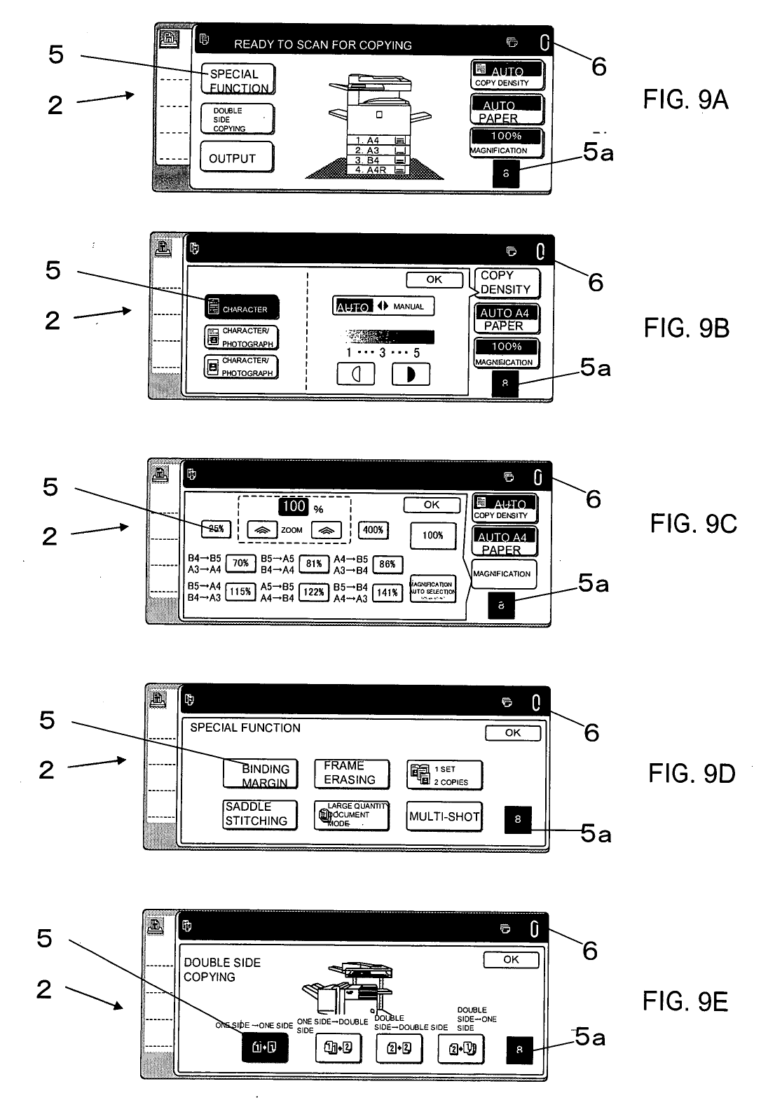

For example, in the case of a standby state, an operation screen as shown in FIG. 2 is usually displayed on the liquid crystal display. Then, when an input-disabled fixed key 7b is detected by the detecting portion 18, the substitute control portion 19 form a space for displaying the touch key 5a substituting for the function of the input-disabled fixed key 7b, by changing the arrangement of the touch key 5. As shown in FIG. 9(A), the substitute control portion 19 shifts the position of the display which is the touch key 5 for switching the copy density, selecting a copy paper sheet, and switching the copy magnification, and makes the touch key 5a substituting for the input-disabled fixed key 7b displayed in the space formed by the shifting operation.

In the case of the operation screen of the copy mode as shown in FIG. 8(A), the substitute control portion 19 makes the substitute touch key 5a displayed by shifting the position of the display which is the touch key 5 for switching the copy density, selecting a copy paper sheet, and switching the copy magnification, as shown in FIG. 9(B).

Further, in the case of the operation screen for changing the copy magnification as shown in FIG. 8(B), the substitute control portion 19 makes the substitute touch key 5a displayed by shifting the position of display which is the touch key 5 for switching the copy density, selecting a copy paper sheet, and switching the copy magnification, as shown in FIG. 9(C).

Further, in the case of the operation screen for selecting a special function as shown in FIG. 8(C), the substitute control portion 19 makes the substitute touch key 5a displayed by shifting the position of display which is the touch key 5 for switching the copy density, selecting a copy paper sheet, and switching the copy magnification, as shown in FIG. 9(D).

Further, in the case of the operation screen for selecting the double side copying as shown in FIG. 8(D), the substitute control portion 19 makes the substitute touch key 5a displayed by shifting the position of display which is the touch key 5 for switching the copy density, selecting a copy paper sheet, and switching the copy magnification, as shown in FIG. 9(E).

Further, the substitute control portion 19 determines whether or not the display apparatus 2 can be used, on the basis of the number of the input-disabled fixed keys 7b. Specifically, in order to display the touch key 5a substituting for the function of the input-disabled fixed key 7b in the display screen, the substitute control portion 19 inhibits the use of the operation panel 1 when the touch keys 5 displayed from the beginning cannot be displayed.

Note that when inhibiting the use of the operation panel 1, the substitute control portion 19 displays the information on the inhibition of the use of the operation panel 1 in a display dedicated region 6a, in order to inform the user that the use of the operation panel 1 is inhibited.

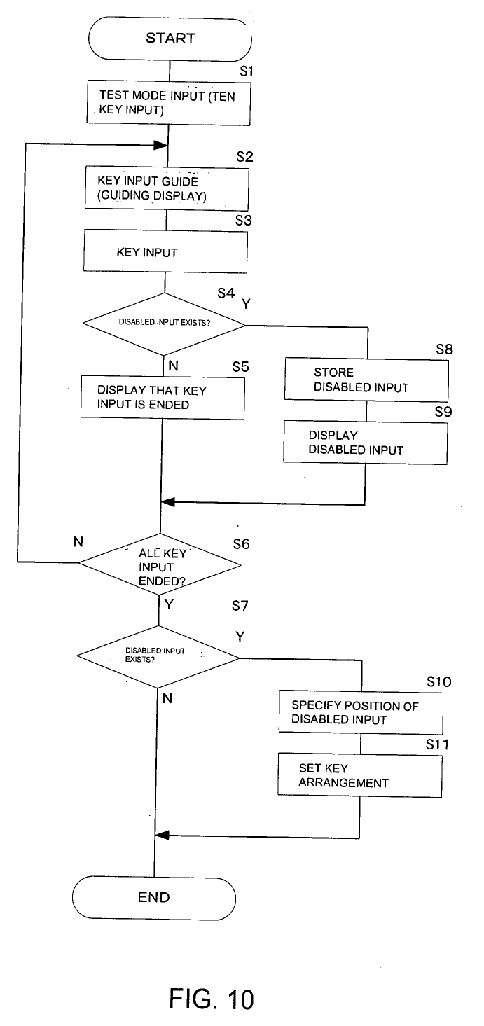

Next, a flow from when the input-disabled fixed key 7b is detected to when the touch key 5a substituting for the input-disabled fixed key 7b is arranged and set in the display screen is explained by using FIG. 10. Note that a key input in the figure means an input from the fixed key 7.

First, the test mode is performed on the basis of the input from the touch key 5 (S1). As shown in FIG. 4(A), FIG. 5(A) and FIG. 6, the substitute control portion 19 displays a plurality of fixed keys 7 in the screen. The detecting portion 18 makes a display to require the user to in sequence input the respective fixed keys 7 in the display screen (S2).

As shown in FIG. 4(B) and FIG. 5(B), the user in sequence press the fixed keys 7 (S3), and the detecting portion 18 checks whether or not the input from the fixed key 7 is sensed (S4). When the detecting portion 18 detects that the input from the fixed key 7 is sensed, the substitute control portion 19 displays the section of the sensed fixed key 7 by changing the color of the section (S5). When the detecting portion 18 detects that the input from the fixed key 7 is not sensed, the substitute control portion 19, upon detection of the input from the touch key 5 by the user, stores the position of the detected input-disabled fixed key 7b (S8), and changes the color of the fixed key (S9).

The detecting portion 18 checks whether or not the checking of all the fixed keys 7 is ended (S6). When the checking is not ended, the detecting portion 18 makes a display in the display screen to require the user to input the fixed key 7 to be subsequently checked (S2), and continues the checking operation until it checks all the fixed keys 7.

When the checking of all the fixed keys 7 is ended, the detecting portion 18 stores the result of the checking operation in the memory. When no input-disabled fixed key 7b exists (S7), the detecting portion 18 ends the test mode as it is, and shifts to the normal operation mode. When an input-disabled fixed key 7b exists (S7), the substitute control portion 19 reads the position of the input-disabled key 7b from the memory (S10), and makes a display as shown in FIG. 7.

The substitute control portion 19 sets an arrangement of the touch key 5, in order to form a space in the display screen, in which the touch key 5a substituting for the function of the detected input-disabled fixed key 7b is displayed (S11). When the space for displaying the substitute touch key 5a is formed, the substitute control portion 19 displays the substitute touch key 5a in the space, and ends the test mode. As shown in FIG. 9, the substitute control portion 19 displays the operation screen set by the control portion 10, and shifts to the normal operation mode.

When the space for displaying the touch key 5a substituting the input-disabled fixed key 7b is provided beforehand, the substitute control portion 19 displays the substitute touch key 5a, without changing the arrangement of the touch key 5 provided beforehand and ends the test mode. As shown in FIG. 9, the control portion 10 makes the normal operation screen displayed, and shifts to the normal operation mode.

### Second Embodiment

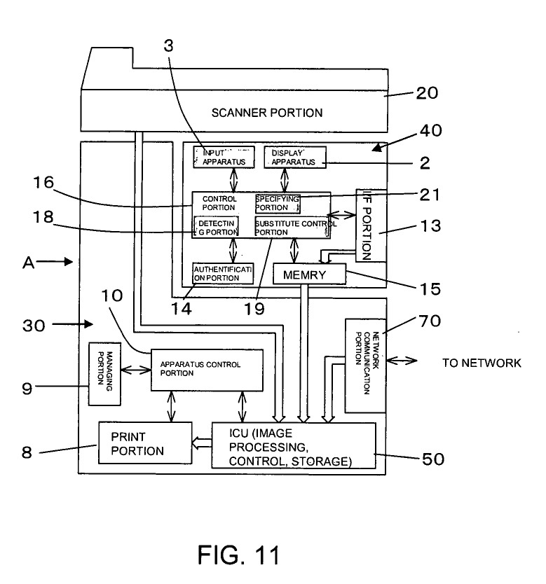

Next, a second embodiment according to the present invention will be explained by using FIG. 2, FIG. 10, and FIG. 11 to FIG. 17. Note that portions the same as those in the first embodiment are denoted by the same reference numerals and characters, the explanation thereof will be omitted, and portions different from those in the first embodiment will be explained.

A display apparatus 2 has an electrostatic touch panel and a liquid crystal display as shown in FIG. 2. The touch panel is an input apparatus which receives an operation input when the panel surface is touched with a finger, a dedicated pen, or the like. The touch panel is constituted by an input region 4 divided into a plurality of sections. Further, the touch panel is constituted by a dedicated transparent screen, and attached so as to cover the upper surface of the liquid crystal display.

Here, the input region 4 is arranged in a matrix form, and an input is sensed by an operation such as touching the inside of the input region. The positional information on the input region 4 is outputted to a control portion 16. When the input region 4 fails due to use over a long period of time or severe environmental changes, the input region 4 is set as an input-disabled region 4b in which the input cannot be performed. The other region in which the input can be performed is set as an input-enabled region 4a in which the input can be performed.

The liquid crystal display is driven and controlled by the control portion 16 so that an input frame 11 indicating an input position in correspondence with the input region 4 and an input guide 12 indicating the input contents of the input frame 11 are displayed in the screen. Note that the input frame 11 means a display of an input key for selecting a function of specifying a paper sheet, enlarging/reducing a copy, adjusting print density, or the like. Further, the input guide 12 means a display of operating states such as an operation mode and an error message, or display of information such as an explanation of functions of the input frame 11. Further, the liquid crystal display has a display dedicated region 6 having no input region. The display dedicated region 6 displays the input guide 12 notifying as to operating states of the image processing apparatus A, information for notifying whether or not the display apparatus 2 can be used, or the like.

Further, an operation panel 1 is controlled by the apparatus control portion 10. The apparatus control portion 10 issues to the control portion 16 an instruction to make the liquid crystal display perform a display of an operation screen corresponding to the operating states, on the basis of an operation command inputted from the touch panel. The control portion 16 makes the input frame 11 and the input guide 12 arranged and displayed in the liquid crystal display in correspondence with the input region 4, on the basis of the instruction from the apparatus control portion 10.

Next, a display portion for displaying the input frame 11 in a manner of avoiding the input-disabled region 4b will be explained. The control portion 16 includes a detecting portion 18 adapted to detect whether or not the input from the each input region 4 can be performed, a specifying portion 21 adapted to specify an input-enabled region 4a in which input from the input region 4 can be performed and an input-disabled region 4b in which input from input region 4 cannot be performed, on the basis of the detection result of the detecting portion 18, and a substitute control portion 19 adapted to control a display apparatus 3 so that the input frame 11 is displayed in a manner of avoiding the specified input-disabled region 4b.

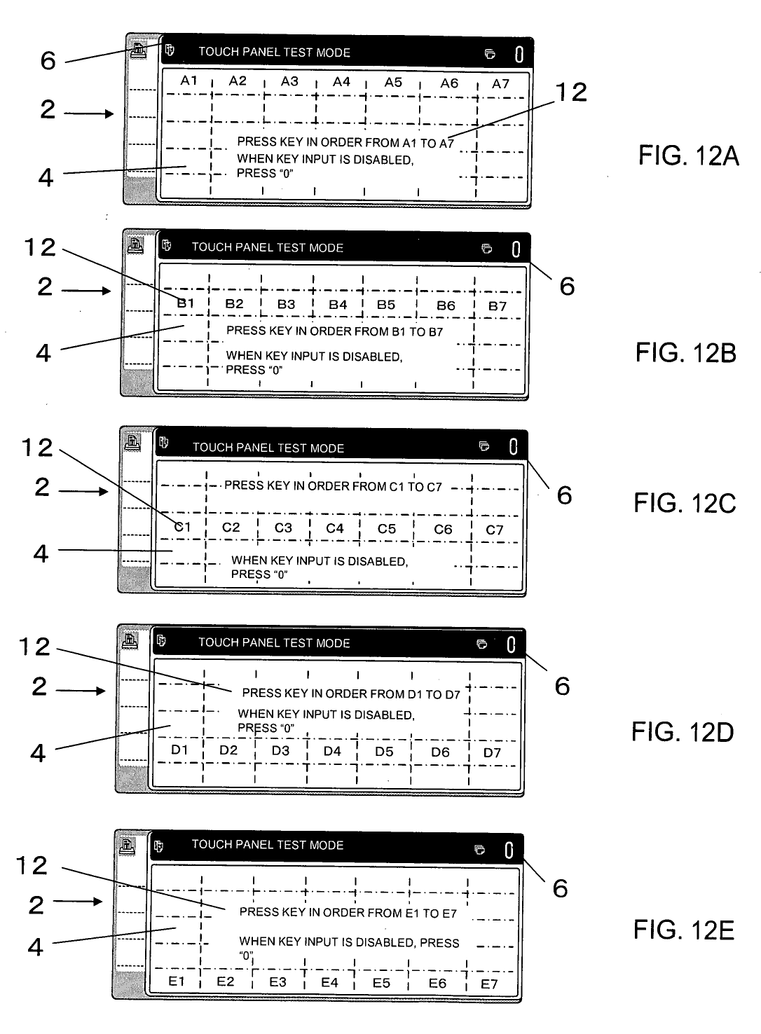

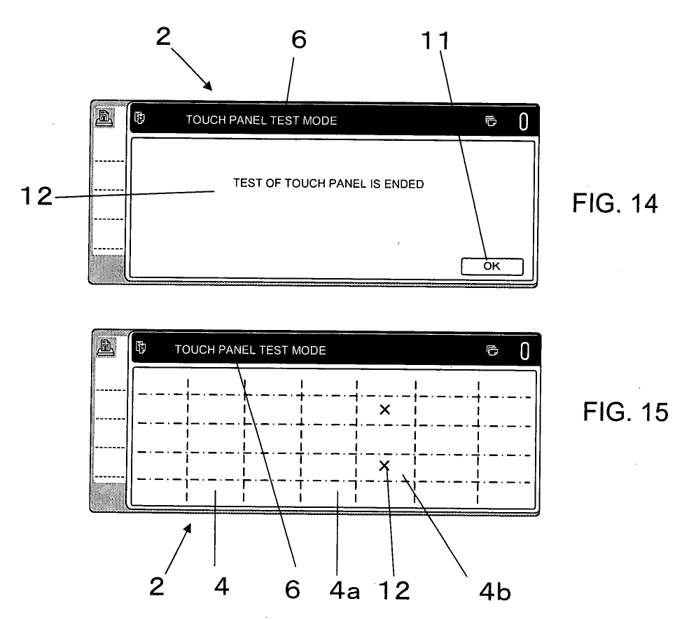

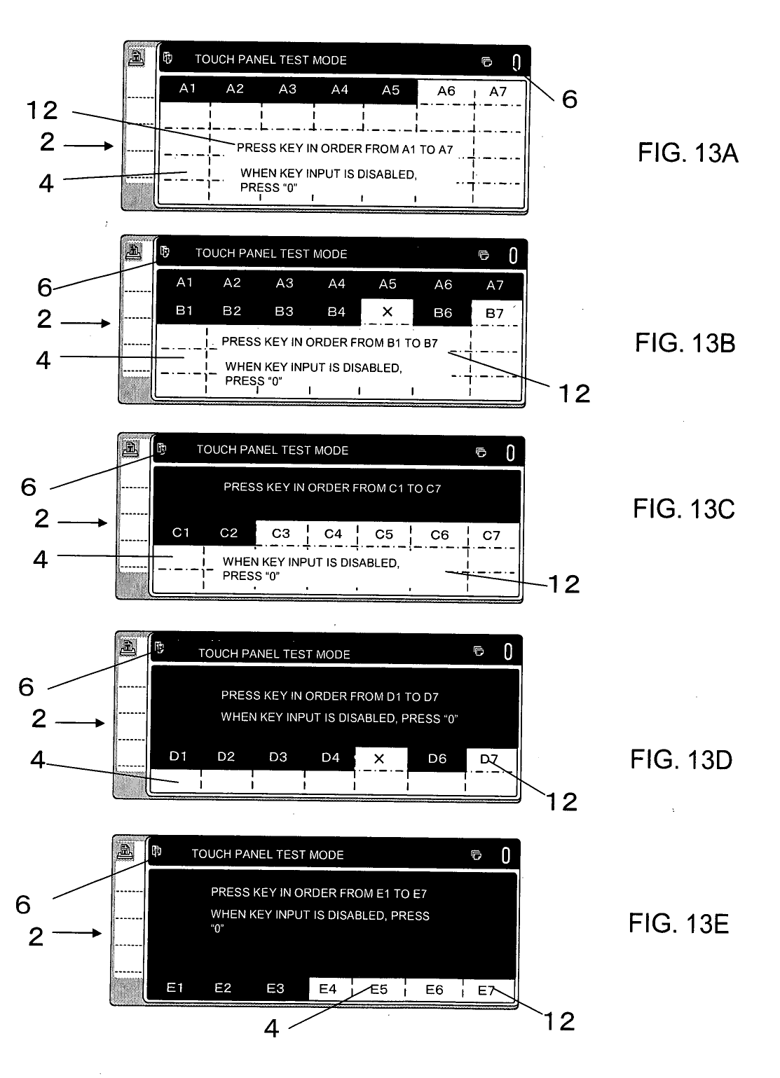

The detecting portion 18 detects the input-disabled region 4b. Specifically, the control portion 16 includes a touch panel test mode, as shown in FIG. 12 and FIG. 13, for detecting whether or not the input from each input region 4 can be performed. The detecting portion 18 starts the operation of the touch panel test mode on the basis of the input from a fixed key 7. The input region 4 is provided with addresses of A1, A2, A3, A4, . . . as shown in FIG. 12. The input guide 12 is displayed so as to make the user in sequence touch the each input region 4 displayed in the display screen.

When the input from the input region 4 is sensed, the detecting portion 18 displays the sensed input region 4, by changing the color of the sensed input region, as shown in FIG. 13. Further, when the input from the input region 4 is not sensed, the detecting portion 18 makes a different display, for example, makes a mark “x” displayed in the section of the input region. Note that in the case where there is an input region 4 in which the input is not sensed, when the preset fixed key 7 (“0” in the present embodiment) is pressed, the detecting portion 18 recognizes the input region as the input region 4 in which the input cannot be recognized. Alternatively, it may also be adapted such that when there is no input for a fixed period of time after the request for input is displayed, the input region requested for input is recognized as the input region 4 in which the input cannot be sensed.

The specifying portion 21 specifies the input-enabled region 4a and the input-disabled region 4b on the basis of the detection result of the detecting portion 18. Specifically, as shown in FIG. 14 and FIG. 15, when the touch panel test mode is ended, the specifying portion 21 stores BS and D5 which are the input-disabled regions 4b, and the input-enabled regions 4a other than the input-disabled regions 4b in a memory 15.

The substitute control portion 19 creates a trouble history including the specified input-disabled regions 4b and stores the trouble history in the memory 15. Here, the trouble history means information on the occurrence date and time, the occurrence place, the occurrence state, or the like, relating to the specified input-disabled region 4b, a failure and the like in the process of conveyance, such as the paper jam of a recording paper, a document or the like, and the double feed of a recording paper or a document or the like.

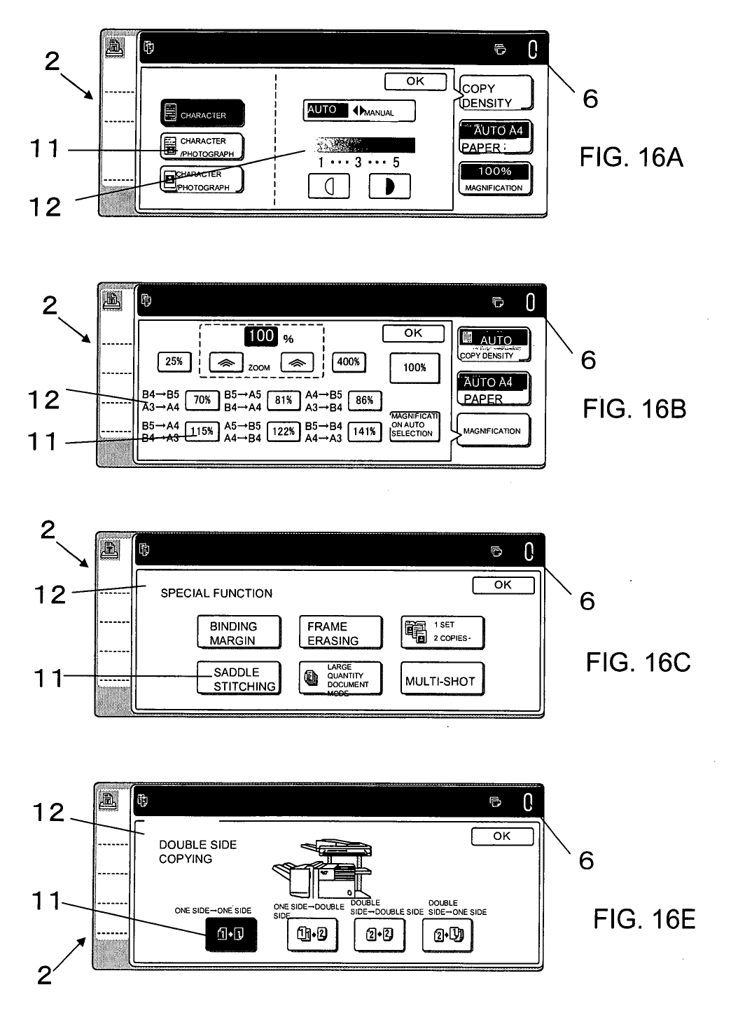

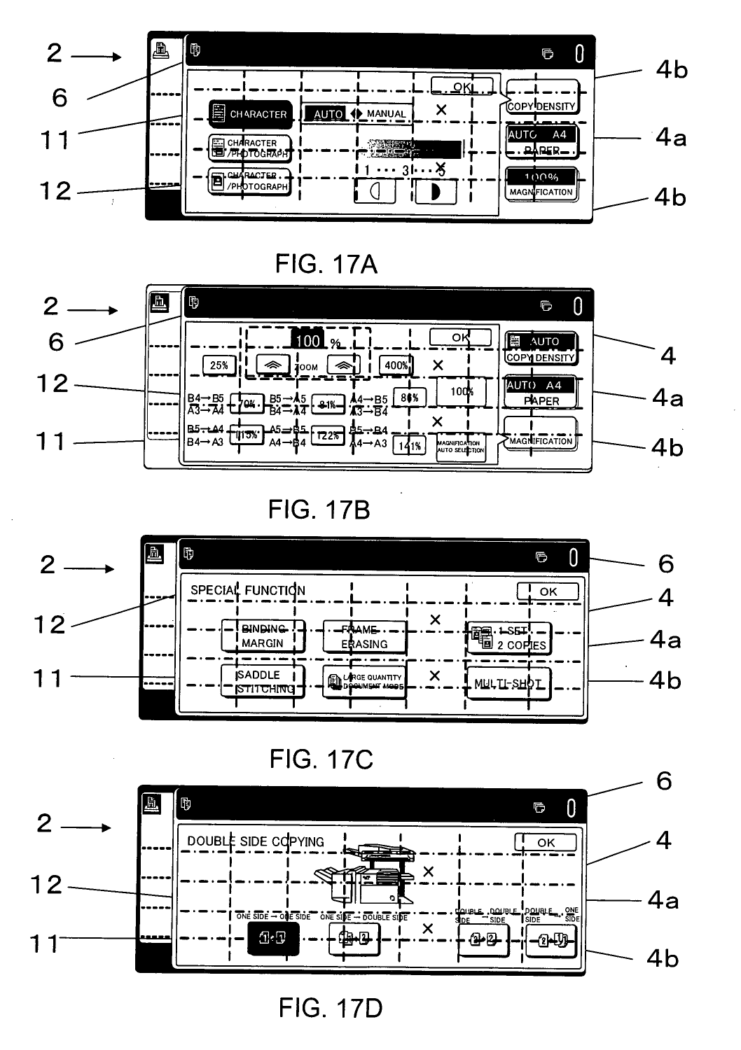

Further, the substitute control portion 19 determines the display position and the display contents of the input frame 11, the input guide 12, and the like, which are displayed in the display screen. Specifically, as shown in FIG. 16 and FIG. 17, the substitute control portion 19 makes the input frame 11 arranged so as to be displayed in correspondence with the input-enabled region 4a, and makes the input guide 12 arranged so as to be displayed in the input-disabled region 4b. Alternatively, nothing is displayed in the input-disabled region 4b. Note that the input frame 11 is displayed so as to be included in the input-enabled region 4a. For example, the input frame 11 is displayed so as to be included in one input-enabled region 4a. Alternatively, the input frame 11 is displayed across a plurality of input-enabled regions 4a.

For example, in the case of the copy mode, an operation screen as shown in FIG. 16(A) is usually displayed on the liquid crystal display. Then, when the input-disabled region 4b is specified by the specifying portion 21, the substitute control portion 19 checks whether or not the input-disabled region 4b and the input frame 11 overlap with each other. When the input frame 11 overlaps with the input-disabled region 4b, as shown in FIG. 17(A), the substitute control portion 19 makes the input-disabled region 4b displayed by shifting the position of display as the input frame 11 for switching the copy density from the input-disabled region 4b.

Further, in the case of the operation screen for changing the copy magnification as shown in FIG. 16(B), the substitute control portion 19 makes the input-disabled region 4b displayed by shifting the position of display as the input frame 11 for specifying the magnification as shown in FIG. 17(B).

Further, in the case of the operation screen for selecting a special function as shown in FIG. 16(C), the substitute control portion 19 makes the input-disabled region 4b displayed by shifting the position of display as the input frame 11 for selecting the function as shown in FIG. 17(C).

Further, in the case of the screen for selecting the double side copying as shown in FIG. 16(D), the substitute control portion 19 makes the input-disabled region 4b displayed by shifting the position of display as the input frame 11 for specifying the magnification as shown in FIG. 17(D).

Further, the substitute control portion 19 determines whether or not the display apparatus 2 can be used on the basis of a ratio of the input-enabled region 4a to the input-disabled region 4b. Specifically, when a plurality of sections is continuously specified as the input-disabled region 4b, for example, when the touch panel is divided into sections and all the sections of a row or a column are specified as the input-disabled region 4b, the substitute control portion 19 inhibits the use of the display apparatus 2.

Further, when determining that the sections of the input-disabled region 4b specified by the specifying portion 21 are more than the sections of the input-enabled region 4a specified by the specifying portion 21, or when a predetermined value or more of the display enable area of the touch panel, for example, 40% or more of the display enable area of the touch panel is detected as the input-disabled region 4b, the substitute control portion 19 inhibits the use of the display apparatus 2.

Note that when inhibiting the use of the display apparatus 2, the substitute control portion 19 displays in the display dedicated region 6 that the use of the display apparatus is inhibited, in order to notify the user that the use of the display apparatus is inhibited.

Next, the flow from when the input-disabled region 4b is detected to when the input frame 11 is arranged and set will be explained by using FIG. 10. Note that a key input in the figure means an input from the input region 4 divided into sections.

First, a touch panel test mode is performed on the basis of the input from the fixed key 7 (S1). As shown in FIG. 12, the display control portion displays a screen divided in correspondence with the plurality of input regions 4. The detecting portion performs a display in the display screen to require the user to in sequence perform input to the each input region 4 (S2).

As shown in FIG. 13, the user in sequence presses the input region 4 (S3), and the detecting portion 18 checks whether or not the input from the input region 4 is sensed (S4). When the detecting portion 18 detects that the input from the input region 4 is sensed, the substitute control portion 19 displays the section of the sensed input region 4 by changing the color of the sensed section (S5). When the detecting portion 18 detects that the input from the input region 4 is not sensed, the substitute control portion 19, upon detection of the input from the fixed key 7 by the user, stores the position of the detected input-disabled region 4b (S8), and changes the display of the input region 4 (S9).

The detecting portion 18 checks whether or not the checking of all the input regions 4 is ended (S6). When the checking of all the input regions is not ended, the detecting portion 18 notifies the user to perform input in the input region 4 to be subsequently checked by displaying the notification in the display screen (S2), and continues the checking operation until it checks all the input regions 4.

As shown in FIG. 14, when the checking of all the input regions 4 is ended, the detecting portion 18 stores the result of the checking in a memory. When there is no input-disabled region 4b (S7), the detecting portion 18 ends the touch panel test mode, and shifts to the normal operation mode. When there is an input-disabled region 4b (S7), the substitute control portion 19 reads the position of the input-disabled region 4b from the memory (S10), and displays the position of the input-disabled region 4b as shown in FIG. 15.

The substitute control portion 19 checks whether or not the position of the specified input-disabled region 4b overlaps with the input frame 11. When the input-disabled region 4b overlaps with the input frame 11, the substitute control portion 19 sets the arrangement of the input frame 11 (S11).

When the setting of the arrangement of the input frame 11 is ended, the substitute control portion 19 ends the touch panel test mode. As shown in FIG. 16, the substitute control portion 19 makes the operation screen, set by the apparatus control portion 10, displayed on the liquid crystal display, and shifts to the normal operation mode.

When the input-disabled region 4b does not overlap with the input frame 11, the substitute control portion 19 ends the touch panel test mode without changing the arrangement of the input frame 11. As shown in FIG. 16, the apparatus control portion 10 displays the normal operation screen, and shifts to the normal operation mode.

Note that the present invention is not limited to the above described embodiments, but numerous modifications and changes can be obviously made therein without departing from the spirit and scope of the present invention. The operation panel according to the present invention can be used not only for the image processing apparatus, but also for electric apparatuses in general which need an operation panel, such as for example, a rice cooker, a washing machine, and an electric air warming apparatus. The operation panel may also be provided with three or more input apparatuses.

In the present invention, the input key substituting for the function of the input-disabled fixed key is formed in the display screen, but the present invention is not limited to this. For example, it may be adapted such that a spare fixed key is provided beforehand, and when an input-disabled fixed key is detected, the spare fixed key substitutes for the function of the input-disabled fixed key.

The spare fixed key may also be provided in a freely projecting manner or in a freely attachable and detachable manner. In this case, a recess is provided in a part of the operation panel, and a connector is provided on the bottom surface of the recess. A fixed key formed as a member separate from the operation panel may also be attached to the recess, so that the fixed key is used as the spare fixed key.

The test mode is started on the basis of the input from the fixed key or the touch key. However, the test mode may also be automatically started on the basis of a predetermined time or the number of times of use, in order to periodically inspect whether or not the input of the operation panel can be performed.

When there are many input-disabled fixed keys, the touch keys substituting for the function of the fixed keys may be reduced so as to be displayed in the operation screen. In this case, since the operable functions are reduced, the input frame for fundamental functions is displayed. The input frame for special input operation is not displayed.

The input-disabled region is explained in relation to the input region in which the input cannot be performed from the display screen, but the present invention is not limited to this. For example, when display cannot be performed in a part of the liquid crystal display, the input region may be rearranged so as to prevent the input frame from being arranged in the part where display cannot be performed.

The electrostatic touch panel is use as the display apparatus, but a contact type display apparatus detecting an input by pressure sensing may also be used. Further, a non-contact type display apparatus detecting an input with light, camera or the like may also be used.

When there are many input-disabled regions, the operation screen may be displayed by reducing the input frame. In this case, since the operable functions are reduced, the input frame for fundamental functions is displayed. The input frame for special input operation is not displayed.

1. An operation panel apparatus comprising:
an operation panel for input operation;
a detecting portion adapted to detect an input-disabled key incapable of performing input in the operation panel; and
a substitute control portion adapted, when the input-disabled key is detected, to control the operation panel to enable the other input-enabled key to cope with the input operation instead of the input-disabled key.

2. An operation panel apparatus,
wherein an operation panel includes an input apparatus having a plurality of fixed keys,
wherein a detecting portion detects an input-disabled fixed key incapable of performing input among the fixed keys, and
wherein when the input-disabled fixed key exists, the other fixed key is adapted to cope with the input instead of the input-disabled fixed key.

3. The operation panel apparatus according to claim 2, wherein the function assigned to the input-disabled fixed key is assigned to the substitute fixed key.

4. The operation panel apparatus according to claim 3, wherein the substitute fixed key is newly provided.

5. The operation panel apparatus according to claim 2, further comprising a plurality of input apparatuses,
wherein the detecting portion has a test mode for making a plurality of fixed keys operated in one of the input apparatuses, and the detecting portion performs the test mode to judge whether the input fixed key is an input-enabled fixed key whose input is effective or the input-disabled fixed key whose input is not effective.

6. The operation panel apparatus according to claim 5, wherein the test mode is operated on the basis of an input operation from the other input apparatus.

7. The operation panel apparatus according to claim 1,
wherein the operation panel includes an input apparatus and a display apparatus,
wherein the input apparatus has fixed keys to which predetermined functions are assigned,
wherein the display apparatus has touch keys formed in a display screen,
wherein the detecting portion detects an input-disabled fixed key incapable of performing input among the fixed keys, and
wherein when the input-disabled fixed key exists, the substitute control portion makes the touch key cope with the input instead of the input-disabled fixed key.

8. The operation panel apparatus according to claim 7,
wherein the detecting portion has a test mode for making a plurality of fixed keys operated,
wherein the detecting portion performs the test mode, to judge whether the fixed key is the input-enabled fixed key whose input is effective or the input-disabled fixed key whose input is not effective, and
wherein the substitute control portion assigns the function assigned to the input-disabled fixed key to the substitute touch key.

9. The operation panel apparatus according to claim 8, wherein the substitute control portion forms the substitute touch key in the display screen.

10. The operation panel apparatus according to claim 9, wherein the substitute control portion secures a space for forming the substitute touch key by changing the display of the display screen.

11. The operation panel apparatus according to claim 1,
wherein the operation panel comprises a display apparatus having a display screen in which input can be performed,
wherein the detecting portion detects an input-disabled region in the display apparatus in which region input cannot be performed, and
wherein when the input-disabled region exists, the substitute control portion controls the display apparatus to perform a display in a manner of avoiding the input-disabled region.

12. The operation panel apparatus according to claim 11, wherein the detecting portion comprises a specifying portion adapted to specify the input-enabled region and the input-disabled region on the basis of the detection result.

13. The operation panel apparatus according to claim 12,
wherein the operation panel comprises an input apparatus having a plurality of fixed keys, and
wherein the detecting portion is operated on the basis of an instruction from the input apparatus.

14. The operation panel apparatus according to claim 11,
wherein the detecting portion comprises a specifying portion adapted to specify the input-disabled region and the input-enabled region on the basis of the detection result,
wherein the display apparatus has an operation screen adapted to display operation contents,
wherein an input frame showing an input position and an input guide showing input contents are displayed in the operation screen, and
wherein the substitute control portion displays the input frame in the input-enabled region, and displays the input guide in the input-disabled region, or inhibits the display.

15. The operation panel apparatus according to claim 14, wherein the substitute control portion determines whether or not the display apparatus can be used, on the basis of a ratio of the input-disabled region to the input-enabled region.

16. The operation panel apparatus according to claim 15,
wherein the display screen is constituted by an input region divided into a plurality of sections, and
wherein when the input-disabled region continuously exists across the plurality of sections, the substitute control portion prohibits the use of the input apparatus.

17. The operation panel apparatus according to claim 15, wherein when the input-disabled region exists, the substitute control portion restrict input by reducing the input frame to be displayed.

18. The operation panel apparatus according to claim 14, wherein the display screen is formed as a touch panel.

19. The operation panel apparatus according to claim 1, wherein when the input-disabled key is detected by the detecting portion, the substitute control portion creates a trouble history including the input-disabled key.

20. An electric apparatus comprising the operation panel apparatus according to claim 1.

21. The electric apparatus according to claim 20, wherein the electric apparatus is adapted to be a copy machine, a printer, a facsimile, a scanner, or a composite machine constituted by combining two or more of the copy machine, the printer, the facsimile and the scanner.
